(19) United States
(12) Patent Application Publication
(10) Pub. No.: US 2026/0026141 A1
(43) Pub. Date: Jan. 22, 2026

(54) MICRO LIGHT-EMITTING DIODE DISPLAY PANEL

(71) Applicant: PlayNitride Display Co., Ltd., MiaoLi County (TW)

(72) Inventors: LOGANATHAN MURUGAN, MiaoLi County (TW); Sheng-Yuan Sun, MiaoLi County (TW); Po-Wei Chiu, MiaoLi County (TW)

(73) Assignee: PlayNitride Display Co., Ltd., MiaoLi County (TW)

(21) Appl. No.: 18/776,269

(22) Filed: Jul. 18, 2024

(51) Int. Cl. H01L 33/58; H01L 25/075; H01L 33/50

(52) U.S. Cl. CPC H10H 20/855; H01L 25/0753; H10H 20/8512; H10H 20/8515

(57) ABSTRACT

A micro light-emitting diode (micro-LED) display panel including a substrate, a first light blocking layer, a second light blocking layer, and a plurality of micro-LEDs is provided. The first light blocking layer is disposed on the substrate. The second light blocking layer is disposed on the first light blocking layer. The second light blocking layer defines a plurality of pixel units arranged in an array. The micro-LEDs are disposed on the first blocking layer. At least one of the micro-LEDs is disposed on each of the pixel units. A gap exists between a part of the second light blocking layer and the first light blocking layer. A filling structure is in the gap. A material of the filling structure is different from a material of the second light blocking layer.

### BACKGROUND

### Technical Field

The disclosure relates to a display panel, and in particular to a micro light-emitting diode (micro-LED) display panel.

### Description of Related Art

With the advancement of display technology, micro-LED display panels have been developed. In addition to using multiple red micro-LED chips, multiple green micro-LED chips, and multiple blue micro-LED chips staggered to form a colorful picture, another type of micro-LED display panel uses a plane layer formed on the display backplane and a retaining wall formed on the plane to form multiple pixel spaces, in which the micro-LED chip is disposed in the pixel space. Then, a wavelength conversion material is filled in the pixel space to convert the color of the light emitted by the light-emitting diode chip into another color, thereby a colorful picture can also be formed.

When fabricating a structure used to accommodate the wavelength conversion material, the plane layer and the retaining wall may be formed separately by the photolithography process. However, due to the instability of the process, there is a gap at the bottom of the plane layer and the retaining wall, and the gap causes the wavelength conversion material to overflow into other pixels through the gap when the wavelength conversion material is subsequently poured into the pixel space. As a result, it is easy to cause color crosstalk between adjacent pixels, or cause the micro-LED display panel to produce impure color output.

### SUMMARY

The disclosure provides a micro light-emitting diode (micro-LED) display panel, which can effectively improve color crosstalk problems of adjacent pixels.

An embodiment of the disclosure provides a micro-LED display panel, which includes a substrate, a first light blocking layer, a second light blocking layer, and a plurality of micro-LEDs. The first light blocking layer is disposed on the substrate, and the second light blocking layer is disposed on the first light blocking layer, in which the second light blocking layer defines multiple pixel units arranged in an array. The micro-LEDs are disposed on the first light blocking layer, and at least one of the micro-LEDs is disposed on each of the pixel units. A gap exists between a part of the second light blocking layer and the first light blocking layer. A filling structure is in the gap. A material of the filling structure is different from a material of the second light blocking layer.

In the micro-LED display panel according to the embodiments of the disclosure, since the filling structure is used to fill the gap to repair defects such as the gap, when the wavelength conversion material is subsequently poured into the pixel unit, the wavelength conversion material does not overflow into an adjacent pixel unit through the gap or cause color crosstalk problems. Therefore, the micro-LED display panel according to the embodiments of the disclosure can achieve color output with higher color purity.

### BRIEF DESCRIPTION OF THE DRAWINGS

FIG. 1A to FIG. 1C are partial cross-sectional schematic views showing the fabrication process of a micro-LED display panel according to an embodiment of the disclosure.

FIG. 2 is a partial cross-sectional view of the micro-LED display panel according to another embodiment of the disclosure.

FIG. 3 is a partial cross-sectional view of the micro-LED display panel according to still another embodiment of the disclosure.

FIG. 4 is a partial cross-sectional view of the micro-LED display panel according to yet another embodiment of the disclosure.

FIG. 5A and FIG. 5B are partial cross-sectional schematic views showing the fabrication process of the micro-LED display panel according to another embodiment of the disclosure.

FIG. 6A and FIG. 6B are partial cross-sectional schematic views showing the fabrication process of the micro-LED display panel according to still another embodiment of the disclosure.

FIG. 7 is a partial cross-sectional view of the micro-LED display panel according to yet another embodiment of the disclosure.

FIG. 8 is a partial cross-sectional view of the micro-LED display panel according to another embodiment of the disclosure.

FIG. 9 is a partial cross-sectional view of the micro-LED display panel according to still another embodiment of the disclosure.

### DESCRIPTION OF THE EMBODIMENTS

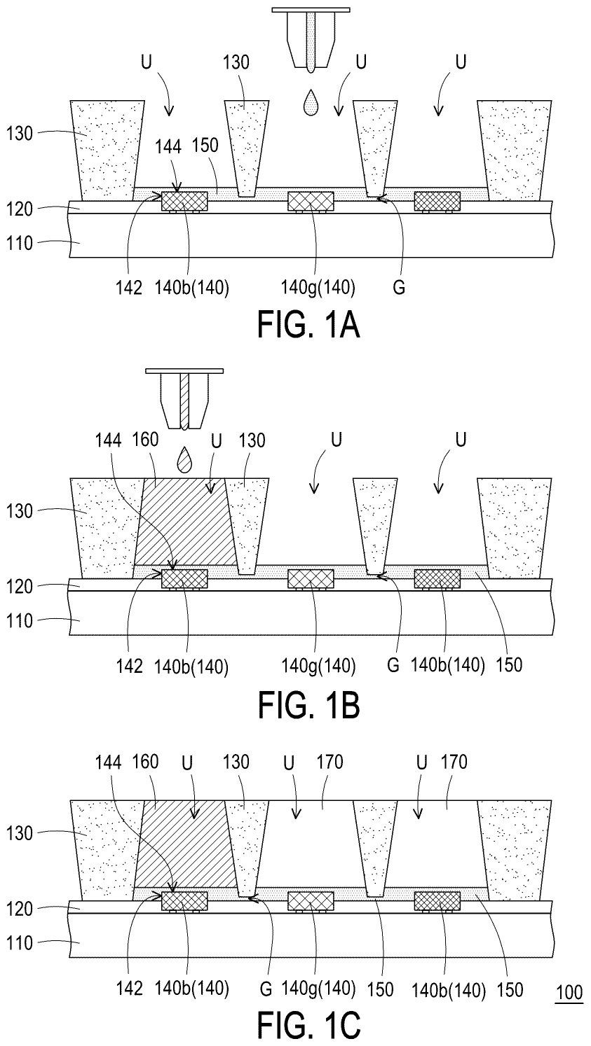

FIG. 1A to FIG. 1C are partial cross-sectional schematic views showing the fabrication process of a micro light-emitting diode (micro-LED) display panel according to an embodiment of the disclosure. Referring to FIG. 1A to FIG. 1C, a micro-LED display panel 100 of this embodiment includes a substrate 110, a first light blocking layer 120, a second light blocking layer 130, and a plurality of micro-LEDs 140. The first light blocking layer 120 is disposed on the substrate 110, the second light blocking layer 130 is disposed on the first light blocking layer 120, and the second light blocking layer 130 exposes a part of the first light blocking layer 120, in which the second light blocking layer 130 defines a plurality of pixel units U arranged in an array. The micro-LEDs 140 are arranged on the first light blocking layer 120, and at least one of the micro-LEDs 140 is disposed on each pixel unit U (one is taken as an example in FIG. 1A to FIG. 1C).

In this embodiment, the substrate 110 is, for example, a circuit backplane, which may be a glass or plastic substrate disposed with conductive lines, or a silicon substrate disposed with conductive lines.

A gap G exists between a part of the second light blocking layer 130 and the first light blocking layer 120. A filling structure 150 is in the gap G. The material of the filling structure 150 is different from the material of the second light blocking layer 130. In this embodiment, the material of the first light blocking layer 120 and the second light blocking layer 130 is, for example, resin or polymer material, which is suitable for the photolithography process. In some embodiments, the material of the first light blocking layer 120 and the second light blocking layer 130 is, for example, a resin material that can absorb light, or a resin material that can reflect light. The filling structure 150 is formed by, for example, curing transparent ink, and the material of the filling structure 150 may be, for example, an acrylic polymer, or the material of the filling structure 150 may be formed by an acrylic polymer mixed with nanoparticles of titanium dioxide or zirconium dioxide, so that the filling structure 150 also has the effect of scattering light.

In the fabrication process of the micro-LED display panel 100 in this embodiment, after the micro-LED 140 is disposed on the substrate 110 and the first light blocking layer 120 and the second light blocking layer 130 are fabricated on the substrate 110 using the photolithography process, defects such as the gap G may occur between the part of the second light blocking layer 130 and the first light blocking layer 120. Therefore, as shown in FIG. 1A, a pixel unit U (such as the pixel unit U in the middle in FIG. 1A) is filled with the material of the filling structure 150. The material of the filling structure 150 overflows into an adjacent pixel unit U (such as the two pixel units U on the left and right in FIG. 1A) through the gap G, and the material of the filling structure 150 fills the gap. Since being formed by, for example, curing transparent ink, the filling structure 150 does not have a negative impact on the color purity of the adjacent pixel unit U even if overflowing to the adjacent pixel unit U through the gap G. Then, after the material of the filling structure 150 is cured by light or heat, or after the material of the filling structure 150 is cured naturally, the filling structure 150 can repair the defects such as the gap G. In this way, when a pixel unit U (such as the pixel unit U on the left in FIG. 1B) is filled with a wavelength conversion material 160 as shown in FIG. 1B, the wavelength conversion material 160 does not overflow to the adjacent pixel unit U through the gap G.

In this embodiment, at least one pixel unit U is disposed with the wavelength conversion material 160. In FIG. 1C, the pixel unit U on the left is disposed with the wavelength conversion material 160 as an example, and other pixel units U may be disposed with an even layer 170. The material of the even layer 170 may be a transparent material, or may be a material formed by a transparent material mixed with scattering particles, in which the scattering particles may scatter lights emitted by the micro-LED 140 to achieve a wider viewing angle. The wavelength conversion material 160 is, for example, a quantum dot material, or a phosphor. In this embodiment, the micro-LED 140 is a micro-LED chip, which may be divided into a blue micro-LED 140b and a green micro-LED 140g. In addition, the wavelength conversion material 160 is, for example, a red quantum dot material, which may convert the blue light emitted by the blue micro-LED 140b into a red light to form a red sub-pixel (that is, the pixel unit on the left in FIG. 1C). In the pixel unit U in the middle in FIG. 1C, the green light emitted by the green micro-LED 140g penetrates the even layer 170 to form a green sub-pixel. In the pixel unit U on the right in FIG. 1C, the blue light emitted by the blue micro-LED 140b penetrates the even layer 170 to form a blue sub-pixel. FIG. 1C shows a partial cross-sectional view of the micro-LED display panel 100. In fact, the micro-LED display panel 100 may include more alternately arranged red sub-pixels, green sub-pixels, and blue sub-pixels, thereby a colorful picture is formed.

In another embodiment, the even layer 170 may not be filled in the space of the pixel units U (such as the two pixel units U in the middle and on the right in FIG. 1C) not filled with the wavelength conversion material 160. In other words, the even layer 170 may be optionally used, that is, the even layer 170 does not have to be used.

In this embodiment, the filling structure 150 extends to at least one pixel unit U adjacent to the gap G, and is disposed on a peripheral surface 142 of the micro-LED 140 in the at least one pixel unit U adjacent to the gap G. In addition, in this embodiment, the filling structure 150 is further disposed on a top surface 144 of the micro-LED 140 in the at least one pixel unit U adjacent to the gap G, which is used as a flat layer or protective layer on the micro-LED 140 for subsequent filling of the wavelength conversion material 160 in the space of the pixel unit U.

In the micro-LED display panel 100 of this embodiment, since the filling structure 150 is used to fill the gap G to repair the defects such as the gap G, when the wavelength conversion material 160 is subsequently poured into the pixel unit U, the wavelength conversion material 160 does not overflow into the adjacent pixel unit U through the gap G or cause color crosstalk problems. Therefore, the micro-LED display panel 100 of this embodiment can achieve color output with higher color purity.

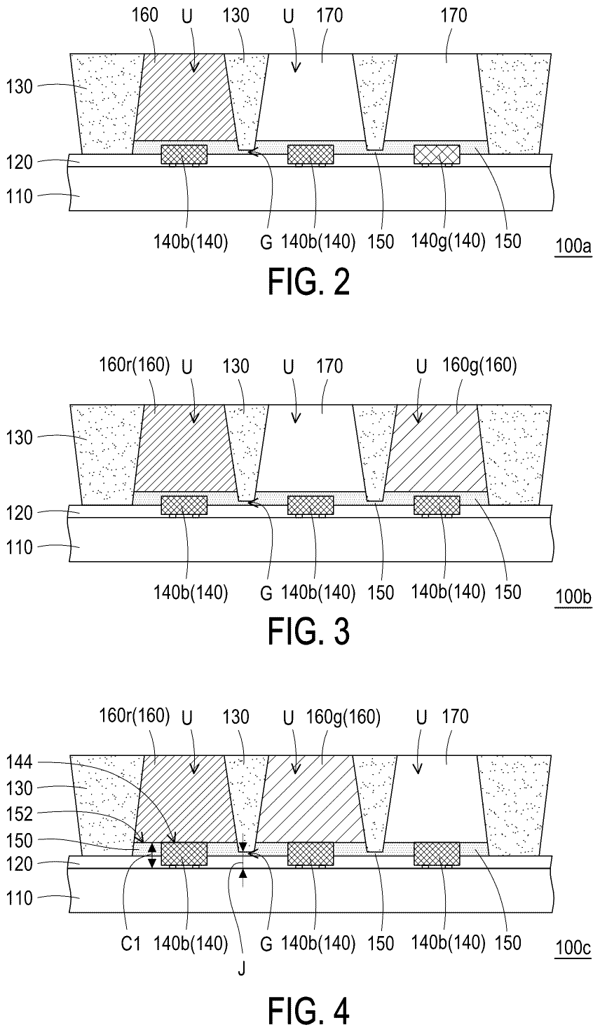

FIG. 2 is a partial cross-sectional view of the micro-LED display panel according to another embodiment of the disclosure. Please refer to FIG. 2. A micro-LED display panel 100a of this embodiment is similar to the micro-LED display panel 100 in FIG. 1C, and the main difference between the two is that in the three pixel unit U in FIG. 1C, the green micro-LED 140g is disposed in the middle, and the two blue micro-LEDs 140b are disposed on the two sides, while in this embodiment, as shown in FIG. 2, the green micro-LED 140g is disposed on one side, and the two blue micro-LEDs 140b are disposed in the middle and another side respectively.

FIG. 3 is a partial cross-sectional view of the micro-LED display panel according to still another embodiment of the disclosure. Please refer to FIG. 3. A micro-LED display panel 100b of this embodiment is similar to the micro-LED display panel 100a in FIG. 2, and the main difference between the two is as follows. In the micro-LED display panel 100b of this embodiment, the green sub-pixel (such as the pixel unit U on the right in FIG. 3) is formed by using the blue micro-LED 140b together with a wavelength conversion material 160g filled in the pixel unit U, in which the wavelength conversion material 160g is, for example, a green quantum dot material, which may convert the blue light emitted by the blue micro-LED 140b into a green light. That is to say, the wavelength conversion material 160 used in this embodiment includes two types, a wavelength conversion material 160r and the wavelength conversion material 160g, in which the wavelength conversion material 160r is the red quantum dot material, and the wavelength conversion material 160g is the green quantum dot material. In this way, the structure in FIG. 3 may also form red sub-pixels, green sub-pixels, and blue sub-pixels, in which the even layer 170 is located in the pixel unit U in the middle, so the blue sub-pixel is, for example, located in the middle.

FIG. 4 is a partial cross-sectional view of the micro-LED display panel according to yet another embodiment of the disclosure. Please refer to FIG. 4. A micro-LED display panel 100c of this embodiment is similar to the micro-LED display panel 100b in FIG. 3, and the main difference between the two is as follows. In the micro-LED display panel 100c of this embodiment, the wavelength conversion material 160g using the green quantum dot is located in the pixel unit U in the middle in FIG. 4, and the even layer 170 is located in the pixel unit U on one side in FIG. 4.

In addition, in this embodiment, a maximum height J of the gap G around at least one pixel unit U with respect to the substrate 110 is smaller than a height C1 of the micro-LED 140 in the at least one pixel unit U with respect to the substrate 110, and in the at least one pixel unit U, the top surface 144 of the micro-LED 140 is exposed outside the filling structure 150. In addition, in this embodiment, in the at least one pixel unit U, an upper surface 152 of the filling structure 150 is flush with the top surface 144 of the micro-LED 140.

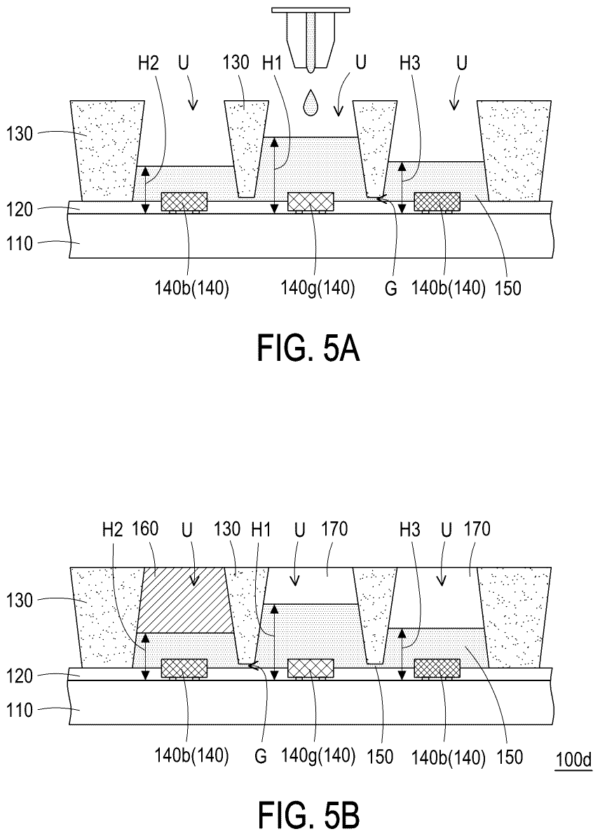

FIG. 5A and FIG. 5B are partial cross-sectional schematic views showing the fabrication process of the micro-LED display panel according to another embodiment of the disclosure. Please refer to FIG. 5A and FIG. 5B. A micro-LED display panel 100d of this embodiment is similar to the micro-LED display panel 100c in FIG. 1C, and the main difference between the two is as follows. In this embodiment, a first height H1 of the filling structure 150 in one pixel unit U with respect to the substrate 110 is different from a second height H2 of the filling structure 150 in another pixel unit U with respect to the substrate 110. Specifically, when the material of the filling structure 150 filling the pixel unit U in the middle has poor fluidity (or a high viscosity coefficient), the material of the filling structure 150 in the pixel unit U in the middle encounters some resistance when flowing to the pixel units U on the two sides through the gap G, as a result, the first height H1 of the filling structure 150 in the pixel unit U in the middle with respect to the substrate 110 is higher than any one of the second height H2 or a third height H3 of the filling structure 150 in the pixel units U on the two sides with respect to the substrate 110.

In addition, in this embodiment, the height (that is, the second height H2) of the filling structure 150 in the pixel unit U (such as the pixel unit U on the left in FIG. 5B) disposed with the wavelength conversion material 160 with respect to the substrate 110 is smaller than the height (that is, the first height H1) of the filling structure 150 in the pixel unit U (such as the pixel unit U in the middle in FIG. 5B) not disposed with the wavelength conversion material 160 with respect to the substrate 110. In this way, the thickness of the wavelength conversion material 160 can be thicker, so as to achieve a better wavelength conversion effect.

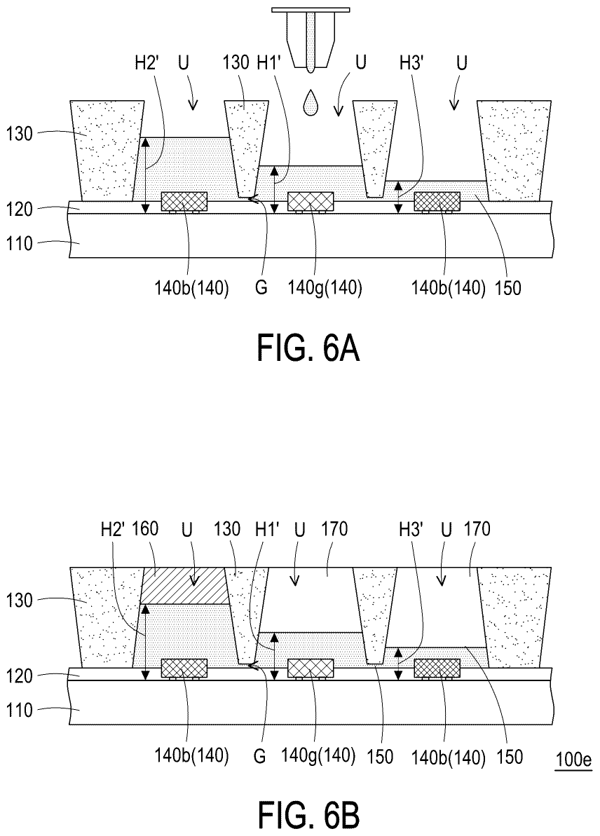

FIG. 6A and FIG. 6B are partial cross-sectional schematic views showing the fabrication process of the micro-LED display panel according to still another embodiment of the disclosure. Please refer to FIG. 6A and FIG. 6B. A micro-LED display panel 100e of this embodiment is similar to the micro-LED display panel 100d in FIG. 5B, and the main difference between the two is as follows. In the step in FIG. 6A, the material of the filling structure 150 is filled in a pixel unit U on one side (for example, the left side) in FIG. 6A. In this embodiment, due to having poor fluidity (or a high viscosity coefficient), the material of the filling structure 150 encounters some resistance when sequentially overflowing to the pixel unit U on the right in FIG. 6A through the two gaps G, as a result, a third height H3′ of the filling structure 150 in the pixel unit U on the right with respect to the substrate 110 is the lowest. On the other hand, when overflowing to the pixel unit U in the middle in FIG. 6A through the gap G, the material of the filling structure 150 also encounters some resistance, as a result, a first height H1′ of the filling structure 150 in the pixel unit U in the middle with respect to of the substrate 110 is of medium height, a second height H2 of the filling structure 150 in the pixel unit U on the left with respect to the substrate 110 is the highest. In short, the second height H2′ is greater than the first height H1′, and the first height H1′ is greater than third height H3′. In other words, the heights of the continuously distributed filling structures 150 decrease in a stepwise manner from left to right. However, in other embodiments, the heights of the continuously distributed filling structures 150 from left to right may also rise in a stepwise manner.

In the two embodiments of FIG. 5A to FIG. 6B, the heights of the filling structures 150 in each pixel unit U are different, depending on from which pixel unit U the material of the filling structure 150 is filled, and the farther away from the filling position, the lower the height of the filling structure 150 of the pixel unit U.

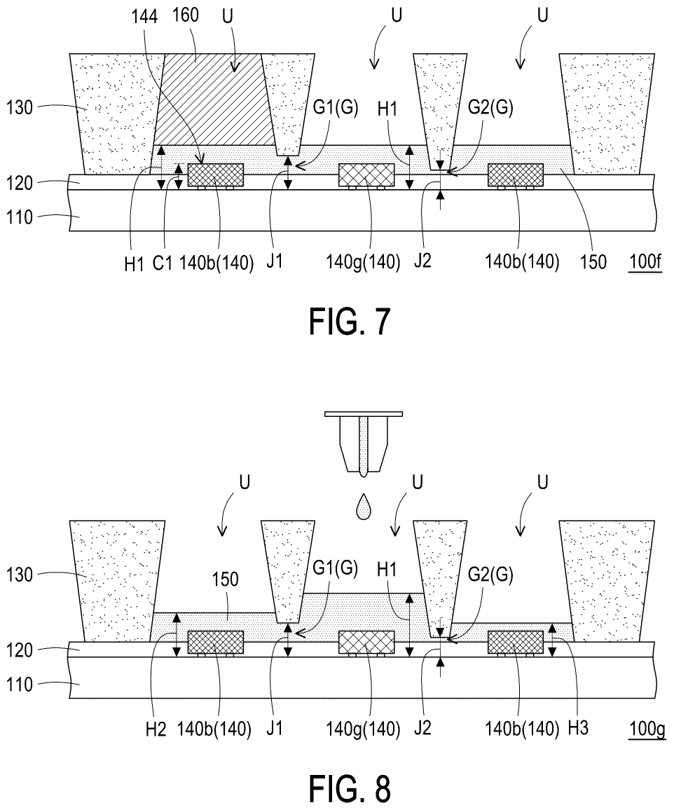

FIG. 7 is a partial cross-sectional view of the micro-LED display panel according to yet another embodiment of the disclosure. Please refer to FIG. 7. A micro-LED display panel 100f of this embodiment is similar to the micro-LED display panel 100 in FIG. 1C, and the main difference between the two is as follows. In the micro-LED display panel 100f of this embodiment, a maximum height (for example, a height J1 of a larger gap G1 with respect to the substrate 110) of a gap around at least one pixel unit U with respect to the substrate 110 is greater than a height C1 of the micro-LED (such as the micro-LED 140 on the left) in the at least one pixel unit U with respect to the substrate 110, and the filling structure 150 in the at least one pixel unit U covers the top surface 144 of the micro-LED 140 in the at least one pixel unit U. In this embodiment, a ratio of the height C1 of the micro-LED 140 in the at least one pixel unit U with respect to the substrate 110 to the height (in this embodiment, for example, equal to the first height H1) of the filling structure 150 in the at least one pixel unit U with respect to the substrate 110 is greater than 0.8 and smaller than 1, for example, 0.85 or 0.9. On the other hand, a height J2 of a smaller gap G2 with respect to the substrate 110 is smaller than the height J1.

In addition, in this embodiment, the gap G between the part of the second light blocking layer 130 and the first light blocking layer 120 is a plurality of gaps of different heights (such as the gaps G1, G2), and the height (in this embodiment, for example, equal to the first height H1) of the filling structure 150 extending to an adjacent pixel unit U with respect to the substrate 110 is greater than the height J1 of the gap G1 of the maximum height with respect to the substrate 110.

FIG. 8 is a partial cross-sectional view of the micro-LED display panel according to another embodiment of the disclosure. Please refer to FIG. 8. A micro-LED display panel 100g of this embodiment is similar to the micro-LED display panel 100f in FIG. 7, and the main difference between the two is as follows. Compared with the material of the filling structure 150 used in FIG. 7, the material of the filling structure 150 of this embodiment has poor fluidity (or a high viscosity coefficient) during filling. Therefore, the first height H1 of the filling structure 150 in the pixel unit U in the middle with respect to the substrate 110 is the highest, and the height (such as the second height H2 and the third height H3) of the filling structure 150 extending to other adjacent pixel units U with respect to the substrate 110 has positive correlation with the size of the gap G between the other adjacent pixel units U and the pixel unit U in the middle. For example, the height J1 of the gap G1 with respect to the substrate 110 is greater, then the height (that is, the second height H2) of the filling structure 150 in the adjacent pixel unit U next to the gap G1 with respect to the substrate 110 is greater. In comparison, the height J2 of the gap G2 with respect to the substrate 110 is smaller, then the height (that is, the third height H3) of the filling structure 150 in the adjacent pixel unit U next to the gap G2 with respect to the substrate 110 is smaller.

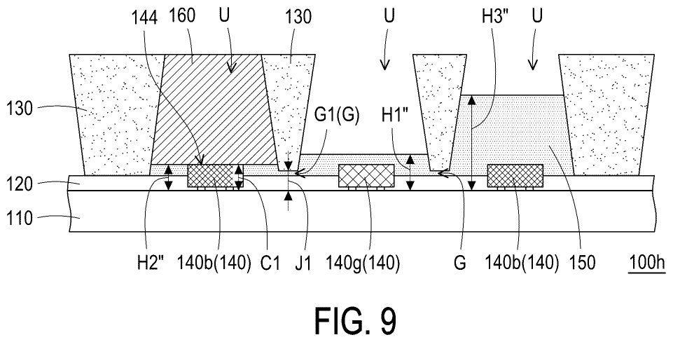

FIG. 9 is a partial cross-sectional view of the micro-LED display panel according to still another embodiment of the disclosure. Please refer to FIG. 9. A micro-LED display panel 100h of this embodiment is similar to the micro-LED display panel 100d in FIG. 5B, the height (such as a second height H2″) of the filling structure 150 in the pixel unit U disposed with the wavelength conversion material 160 with respect to the substrate 110 is smaller than the height (such as any one of a first height H1″ or a third height H3″) of the filling structure 150 in the pixel unit U not disposed with the wavelength conversion material with respect to the substrate 110 in both embodiments. In addition, furthermore, the filling structure 150 in the pixel unit U disposed with the wavelength conversion material 160 (for example, the red quantum dot material) does not cover the top surface 144 of the micro-LED 140. In this way, the wavelength conversion material 160 can be thicker, and the wavelength conversion efficiency and the color purity are further improved. In this embodiment, the height J1 of the gap G1 around the pixel unit U with respect to the substrate 110 is smaller than the height C1 of the micro-LED 140 with respect to the substrate 110, and the filling structure 150 does not cover the top surface 144 of the micro-LED 140 in the pixel unit U. However, in other embodiments, when the height J1 is greater than the height C1, then the filling structure 150 in the pixel unit U covers the top surface 144 of the micro-LED 140.

In summary, in the micro-LED display panel according to the embodiments of the disclosure, since the filling structure is used to fill the gap to repair the defects such as the gap, when the wavelength conversion material is subsequently poured into the pixel unit, the wavelength conversion material does not overflow into the adjacent pixel unit through the gap or cause color crosstalk problems. Therefore, the micro-LED display panel according to the embodiments of the disclosure can achieve color output with higher color purity.

What is claimed is:

1. A micro light-emitting diode (micro-LED) display panel, comprising:
a substrate;
a first light blocking layer, disposed on the substrate;
a second light blocking layer, disposed on the first light blocking layer, wherein the second light blocking layer defines a plurality of pixel units arranged in an array; and
a plurality of micro-LEDs, disposed on the first light blocking layer, wherein at least one of the micro-LEDs is disposed on each of the pixel units,
wherein a gap exists between a part of the second light blocking layer and the first light blocking layer, wherein a filling structure is in the gap, and a material of the filling structure is different from a material of the second light blocking layer.

2. The micro-LED display panel as claimed in claim 1, wherein the filling structure extends to at least one pixel unit adjacent to the gap, and is disposed on a peripheral surface of the micro-LED in the at least one pixel unit adjacent to the gap.

3. The micro-LED display panel as claimed in claim 2, wherein the filling structure is further disposed on a top surface of the micro-LED in the at least one pixel unit adjacent to the gap.

4. The micro-LED display panel as claimed in claim 2, wherein a first height of the filling structure in one of the pixel units with respect to the substrate is different from a second height of the filling structure in another one of the pixel units with respect to the substrate.

5. The micro-LED display panel as claimed in claim 1, wherein at least one of the pixel units is disposed with a wavelength conversion material.

6. The micro-LED display panel as claimed in claim 5, wherein a height of the filling structure in the pixel unit disposed with the wavelength conversion material with respect to the substrate is smaller than a height of the filling structure in the pixel unit not disposed with the wavelength conversion material with respect to the substrate.

7. The micro-LED display panel as claimed in claim 1, wherein the gap between the part of the second light blocking layer and the first light blocking layer comprises gaps of different heights, and a height of the filling structure extending to an adjacent pixel unit with respect to the substrate is greater than a height of a gap of a maximum height with respect to the substrate.

8. The micro-LED display panel as claimed in claim 1, wherein a maximum height of a gap around at least one of the pixel units with respect to the substrate is greater than a height of the micro-LED in the at least one of the pixel units with respect to the substrate, and the filling structure in the at least one of the pixel units covers a top surface of the micro-LED of the at least one of the pixel units.

9. The micro-LED display panel as claimed in claim 8, wherein a ratio of the height of the micro-LED in the at least one of the pixel units with respect to the substrate to a height of the filling structure in the at least one of the pixel units with respect to the substrate is greater than 0.8 and smaller than 1.

10. The micro-LED display panel as claimed in claim 1, wherein a maximum height of a gap around at least one of the pixel units with respect to the substrate is smaller than a height of the micro-LED in the at least one of the pixel units with respect to the substrate, and in the at least one of the pixel units, a top surface of the micro-LED is exposed outside the filling structure.

11. The micro-LED display panel as claimed in claim 10, wherein in the at least one of the pixel units, two upper surfaces of the filling structure are flush with a top surface of the micro-LED.
